(19) United States
(12) Patent Application Publication
(10) Pub. No.: US 2010/0201447 A1
(43) Pub. Date: Aug. 12, 2010

(54) Radio-frequency circuit

(75) Inventors: Akira Hyogo, Kashiwa-shi (JP); Satoshi Tanaka, Tokyo (JP); Tetsuro Sawai, Hashima-shi (JP); Kenichi Agawa, Yokohama-shi (JP); Hirotada Honma, Tokyo (JP); Ryutaro Saito, Toride-shi (JP); Tomoki Hikichi, Kamagaya-shi (JP); Keitaro Sekine, Tokyo (JP)

Correspondence Address: STAAS & HALSEY LLP, SUITE 700, 1201 NEW YORK AVENUE, N.W., WASHINGTON, DC, 20005, US

(73) Assignee: SEMICONDUCTOR TECHNOLOGY ACADAMIC RESEARCH CENTER, Yokohama (JP)

(21) Appl. No.: 12/662,530

(22) Filed: Apr. 21, 2010

Related U.S. Application Data
(62) Division of application No. 11/354,231, filed on Feb. 15, 2006.

(30) Foreign Application Priority Data
Feb. 17, 2005 (JP) 2005-41115

(51) Int. Cl. H03F 3/16

(52) U.S. Cl. 330/277

(57) ABSTRACT

A radio-frequency circuit comprises a low-noise amplifier, an NMOS mixer for converting a radio-frequency signal output from the low-noise amplifier into an intermediate-frequency signal, a polyphase filter for removing image noises, and a PMOS mixer for converting the intermediate-frequency signal passed through the polyphase filter into a baseband signal.

### CROSS-REFERENCE TO RELATED APPLICATIONS

This application is a divisional of U.S. patent application Ser. No. 11/354,231, filed Feb. 15, 2006, now pending. This application is based upon and claims the priority of Japanese application no. 2005-41115, filed Feb. 17, 2005, and U.S. patent application Ser. No. 11/354,231, Feb. 15, 2006, the contents being incorporated herein by reference.

### TECHNICAL FIELD

The present invention relates to a radio-frequency circuit and, more particularly, to a radio-frequency circuit with a MOS structure.

### BACKGROUND ART

Radio-frequency circuits used for the receiver circuits of mobile telephones, wireless LANs, wireless tags, etc. have traditionally been constructed with bipolar devices but, in recent years, with advances in miniaturization technology and resulting improvements in the performance of CMOS devices, work has been proceeding on constructing such radio-frequency circuits using CMOS circuits.

If the radio-frequency circuit can be constructed from a MOS integrated circuit, the cost and power consumption of the radio-frequency circuit can be reduced while achieving a higher integration level, with the additional advantage that the radio-frequency circuit can be fabricated using the same process as for logic circuits.

In the prior art, it is known to provide a radio-frequency receiver circuit of MOS structure having a CMOS circuit in a direct-conversion receiver circuit that converts the frequency by using a local oscillator signal of the same frequency as the input signal. There is also proposed a superheterodyne receiver circuit having two stages of NMOS mixers (S. Tadjpour et al., “A 900-MHz Dual-Conversion Low-IF GSM Receiver in 0.35-11 m CMOS,” IEEE Journal of Solid-State Circuits, Vol. 36, No. 12, pp. 1992-2002, December 2001).

However, a radio-frequency receiver circuit with a MOS structure has the following problems yet to be solved.

First, a MOS structure can cause large 1/f noise. As shown in FIG. 17a, in an NMOS transistor, the width of, the channel through which electrons flow from an N-type source 92 to an N-type drain 93 formed in a P-type substrate is controlled by the voltage applied to its gate 94. If there is an imperfection or distortion in a gate oxide film 96 that separates the gate 94 from the channel 95 then, due to the energy state formed at the gate oxide film 96, the electrons flowing through the channel 95 may be captured by the gate oxide film 96, or the electrons captured by the gate oxide film 96 may be released into the channel 95, resulting in the generation of noise. In the figure, reference numeral 97 indicates aluminum wiring. As the noise power np is inversely proportional to the frequency f, as shown in FIG. 17b, this noise is called the 1/f noise; as is apparent from the figure, the noise is large in the low-frequency region, especially at or near the DC, which can have a significant impact on the baseband signal.

Secondly, MOS devices have the disadvantage of a low current-driving capability, and hence the efficiency for converting a change in input voltage into a change in current is poor. Accordingly, in applications where large gain is needed, the device size must be increased. However, if the size is increased, the size of the drain 93 of the NMOS in FIG. 17a also increases, as a result of which the area of the NP junction forming the interface between the drain 93 and the P-type substrate increases, increasing its parasitic capacitance and adversely affecting proper circuit operation. Furthermore, in the case of a PMOS circuit in which holes are the carriers, it is twice the size of the NMOS circuit.

NWM NMOS has better frequency characteristics than PMOS and, considering the second point above, it is desirable to use NMOS for the radio-frequency circuit. However, as described in the first point above, NMOS has the disadvantage that it can cause large 1/f noise, thus introducing much noise into the baseband signal.

### BRIEF DESCRIPTION OF THE DRAWINGS

FIG. 1 is a block diagram showing a radio-frequency circuit according to a first embodiment of the present invention.

FIG. 2 is a diagram for explaining the operation of the radio-frequency circuit according to the first embodiment.

FIG. 3 is a diagram schematically showing a low-noise amplifier 10 according to the first embodiment.

FIG. 4 is a detailed circuit diagram of the low-noise amplifier 10 according to the first embodiment.

FIG. 5 is a circuit diagram showing another example of the low-noise amplifier 10 according to the first embodiment.

FIG. 6 is a diagram showing an NMOS mixer 20 according to the first embodiment.

FIGS. 7a and 7b are diagrams for explaining the operation of a Gilbert cell that forms the NMOS mixer 20.

FIG. 8 is a detailed circuit diagram of a polyphase filter 30 according to the first embodiment.

FIG. 9 is a detailed circuit diagram of a PMOS mixer 40 according to the first embodiment.

FIG. 10 is a diagram showing a local oscillation circuit used for the mixer according to the first embodiment.

FIG. 11 is a block diagram showing a radio-frequency circuit according to a second embodiment of the present invention.

FIG. 12 is a detailed circuit diagram of a mixer according to the second embodiment.

FIG. 13 is a diagram showing one specific example of a negative resistance circuit 80 according to the second embodiment.

FIG. 14a is a diagram showing a plurality of resonant circuits used in place of inductors L71 and L72 in the second embodiment, and FIG. 14b is a diagram showing LC circuits connected in a staggered fashion in order to enlarge the center frequency band.

FIG. 15 is a diagram showing the results of a simulation which was conducted by making the current flowing to an NMOS circuit different from the current flowing to a PMOS circuit in the second embodiment.

FIG. 16 is a diagram showing the results of the simulation of FIG. 15 as a function of the current value of the NMOS circuit

FIG. 17a is a diagram showing a conventional NMOS field-effect transistor, and FIG. 17b is a diagram showing a graph of 1/f noise inherent to a MOS structure.

### DISCLOSURE OF THE INVENTION

In view of the above problem, it is an object of the present invention to overcome the shortcoming of the radio-frequency circuit of MOS structure.

To achieve the above object, a radio-frequency circuit according to a first aspect of the present invention comprises: a low-noise amplifier; an NMOS mixer for frequency-converting an output of the low-noise amplifier; a filter for introducing a phase shift into an output of the NMOS mixer; and a PMOS mixer for frequency-converting an output of the filter.

The filter can be constructed using at least one polyphase filter.

The low-noise amplifier can be constructed using a low-noise amplification circuit and at least one gain-varying circuit provided at an output end of the low-noise amplification circuit, and the gain-varying circuit can be constructed using a capacitor and a switching device.

A radio-frequency circuit according to a second aspect of the present invention comprises: an NMOS circuit acting as a low-noise amplifier; and a PMOS circuit for selecting a load for the NMOS circuit by switching.

The NMOS circuit can be connected to a power supply via an inductor, and the inductor can be grounded via a negative resistance circuit. Instead of the inductor, a plurality of resonant circuits may be provided, or LC circuits connected in a ladder configuration may be provided.

Provisions may be made so that a larger current flows in the NMOS circuit than in the PMOS circuit.

A low-noise amplifier according to a third aspect of the present invention comprises: a low-noise amplification circuit; and at least one gain-varying circuit provided at an output end of the low-noise amplification circuit, the gain-varying circuit comprising a capacitor and a switching device.

In the first aspect of the present invention, with the provision of the NMOS mixer that handles radio-frequency signals and the PMOS mixer that follows the NMOS mixer, a radio-frequency circuit permitting high packing density and having good frequency characteristics and low 1/f noise can be achieved.

In the second aspect of the present invention, as the mixer is constructed using the NMOS circuit as the LNA and the PMOS circuit as the switching circuit, a radio-frequency circuit permitting high packing density and having good frequency characteristics and low 1/f noise can be achieved, as in the first aspect.

Further, by connecting the NMOS circuit to the power supply via inductors, resonant circuits, or ladder-type LC circuits, it becomes possible to ensure a high gain over a prescribed frequency range and, by further connecting the negative resistance circuit, it becomes possible to cancel out the resistance. Furthermore, the noise characteristic can be improved by making provisions so that a larger current flows in the NMOS circuit than in the PMOS circuit.

In the third aspect of the present invention, as the gain of the low-noise amplifier is made variable at the output end, the gain can be varied without affecting the radio-frequency input signal.

### BEST MODE FOR CARRYING OUT THE INVENTION

FIG. 1 is a block diagram of a radio-frequency circuit according to a first embodiment of the present invention. The radio-frequency circuit of this embodiment is a receiver circuit, and comprises a low-noise amplifier (LNA) 10 having low noise figure and provided at the front end, an NMOS mixer 20 for converting a radio-frequency signal output from the LNA 10 into an intermediate-frequency signal, a polyphase filter 30 for introducing a phase shift, and a PMOS mixer 40 for converting the output of the polyphase filter 30 into a baseband signal.

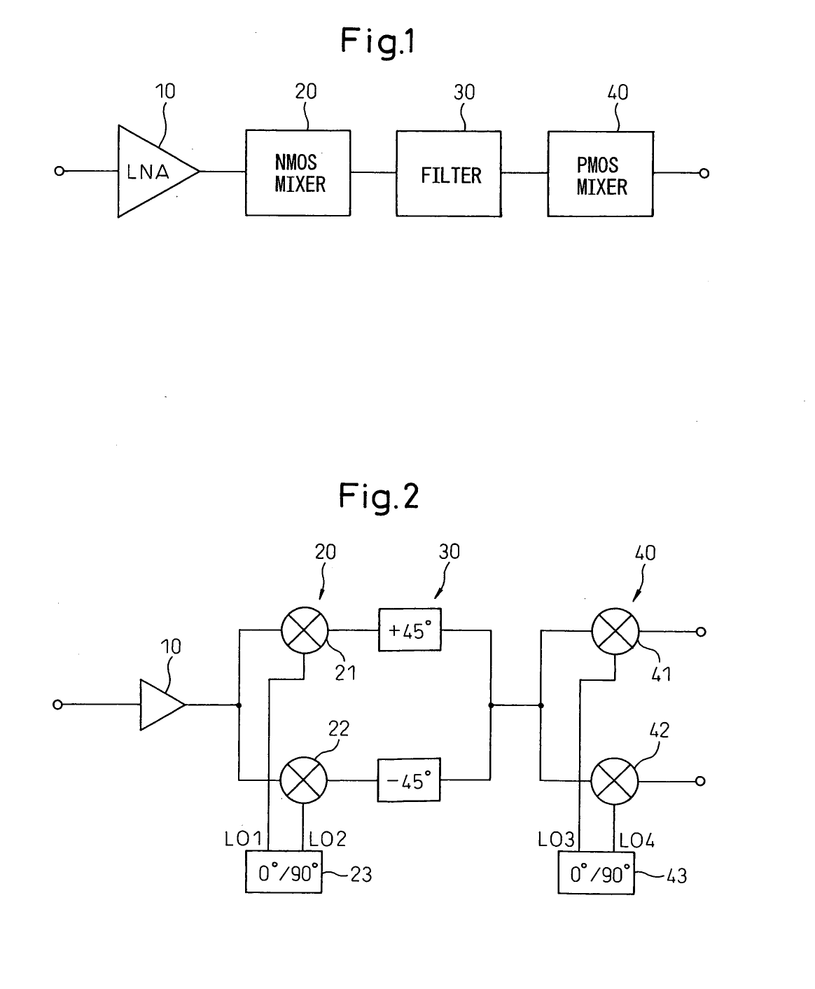

FIG. 2 is a diagram for illustrating the operation of the radio-frequency circuit of this embodiment. The NMOS mixer 20 and the PMOS mixer 40 each comprise two multipliers 21 and 22 or 41 and 42 constructed from NMOS circuits or PMOS circuits, respectively. Assuming that the center frequency of the received radio-frequency (RF) signal is, for example, 5 GHz, the 5-GHz RF signal output from the LNA 10 is supplied to the multipliers 21 and 22. On the other hand, a local oscillation circuit 23 generates two different local signals LO1 and LO2 of a frequency of 4.9 GHz but displaced in phase by 90°, and supplies them to the respective multipliers 21 and 22. In the multipliers 21 and 22, the received 5-GHz radio-frequency signal is multiplied by the respective 4.9-GHz local signals. The resulting 100-MHz intermediate-frequency (IF) signals displaced in phase by 90° are shifted in phase by +45° and −45°, respectively, in the polyphase filter 30, and then combined together to produce an IF signal without image noise. The IF signal is then fed into the PMOS mixer 4 and multiplied in the multipliers 41 and 42 by local signals supplied from a local oscillation circuit 43, and the baseband signal is thus obtained.

As will be described in detail below, in this embodiment, as two stages of mixers are provided, that is, as the NMOS mixer having a good frequency characteristic is used as the mixer that handles the radio-frequency signal at the input stage, and the PMOS mixer is used as the mixer that performs conversion to baseband at the output stage, the radio-frequency circuit of this embodiment has good frequency characteristics and provides low 1/f noise at or near DC.

The parts constituting the radio-frequency circuit of this embodiment will be described in detail below.

### (Low-Noise Amplifier)

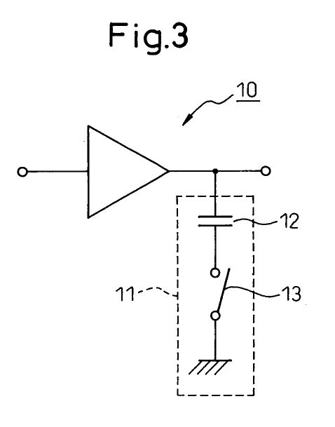

Generally, the strength of the radio-frequency signal that is input to the low-noise amplifier changes in various ways and, if an excessive input signal occurs, the circuit may become saturated. In this embodiment, the gain is made variable in order to prevent circuit saturation. For this purpose, the low-noise amplifier is constructed so that a capacitor can be inserted in parallel at the output side in order to relieve any excessive input signal. FIG. 3 shows a simplified schematic of the low-noise amplifier 10. A gain-varying circuit 11 constructed from a series circuit of a capacitor 12 and a switch 13 is disposed on the output side of a low-noise amplification circuit, and the magnitude of the signal to be input to the mixer 2 at the next stage is limited by turning on the switch 13. In this embodiment, as the gain is varied at the output side of the low-noise amplifier, the disadvantageous effect on the received radio-frequency signal can be reduced compared with the case where the gain is varied on the input side.

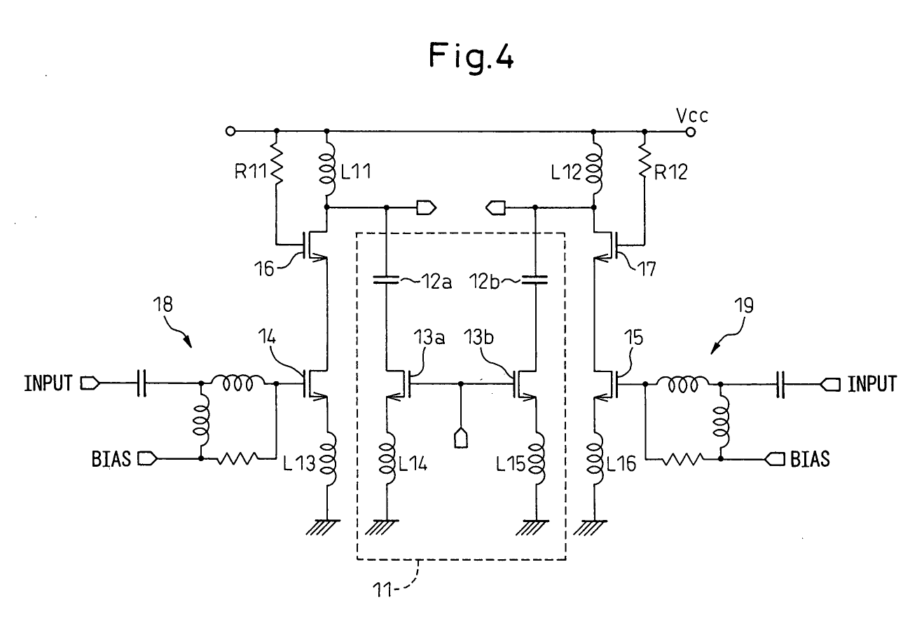

FIG. 4 is a detailed circuit diagram of the low-noise amplifier 10. The low-noise amplifier 10 of this embodiment, constructed in a MOS structure and operated differentially, comprises a low-noise amplification circuit having NMOS FETs 14 to 17 and a gain-varying circuit 11 having capacitors 12a and 12b and NMOS FETs 13a and 13b. The FETs 14 and 15 in the low-noise amplification circuit each convert a voltage of a radio-frequency input signal into a current. The input signals are respectively passed through LLC circuits 18 and 19 for impedance matching and applied to the gates of the respective FETs 14 and 15. The FETs 16 and 17 are connected as cascode transistors in order to prevent the gains of the FETs 14 and 15 from dropping when feedback occurs due to variations in load. As shown, the gates of the FETs 16 and 17 are connected to the power supply via resistors R11 and R12, respectively, and their drains are connected to the power supply via coils L11 and L12, respectively. The output of the low-noise amplifier is produced from the differential outputs from the drains of the FETs 16 and 17. A series circuit consisting of the capacitor 12a and the FET 13a is connected to one of the differential output ends, and is grounded via an inductor L14. A series circuit consisting of the capacitor 12b and the FET 13b is connected to the other differential output end, and is grounded via the inductors L14 and L15. A switching signal is applied simultaneously to the gates of the FETs 13a and 13b. In this circuit, if the output of an excessive signal occurs, the switching signal is applied to the gates of the FETs 13a and 13b, causing the FETs 13a and 13b to turn on and thus grounding the output ends via the respective capacitors 12a and 12b to prevent the excessive signal from being applied to the circuit at the next stage. In this way, the saturation of the circuit at the next stage can be prevented.

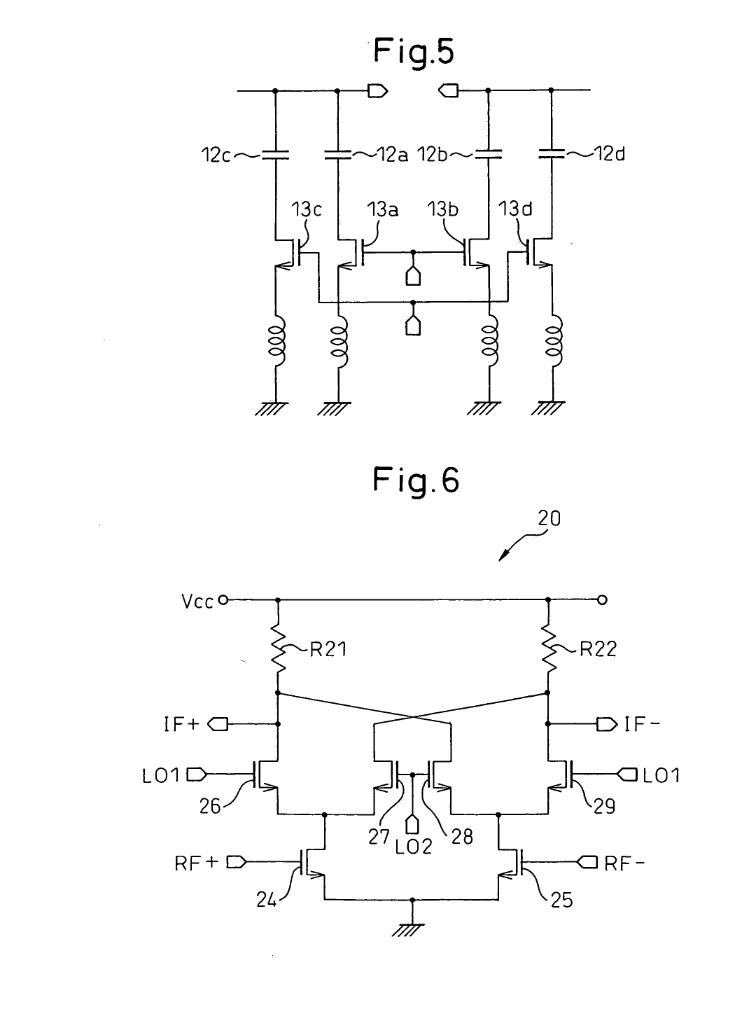

Further, as shown in FIG. 5, when capacitors 12c and 12d, the size being different from that of the capacitors 12a and 12b, and FETs 13c and 13d are added to form additional series circuits, it becomes possible to control the gain in multiple steps. The number of such capacitor/switch series circuits can be suitably selected according to the circuit design.

(NMOS Mixer)

FIG. 6 shows one example of the NMOS mixer 20 of this embodiment. The NMOS mixer 20 uses a Gilbert cell where differential signals are input and output, and comprises NMOS field-effect transistors (FETs) 24 to 29 and resistors R21 and R22. The NMOS FETs 24 and 25 each have a radio-frequency input. The NMOS FET 24 is connected to the differential pair NMOS FETs 26 and 27, while the NMOS FET 25 is connected to the differential pair NMOS FETs 28 and 29. The FETs 26 and 28 each forming one part of each differential pair are connected to the load resistor R21, and the FETs 27 and 29, each forming the other part of each differential pair, are connected to the load resistor R22. The 5-GHz radio-frequency (RF) signal from the LNA 1 is applied as differential inputs to the gates of the FETs 24 and 25, while the 4.9-GHz local signals LO1 and LO2 displaced in phase by 90° are applied to the gates of the FETs 26 and 29 and the gates of the FETs 27 and 28, respectively. The intermediate-frequency (IF) signal, the output of the NMOS mixer, is obtained from the load resistors R21 and R22.

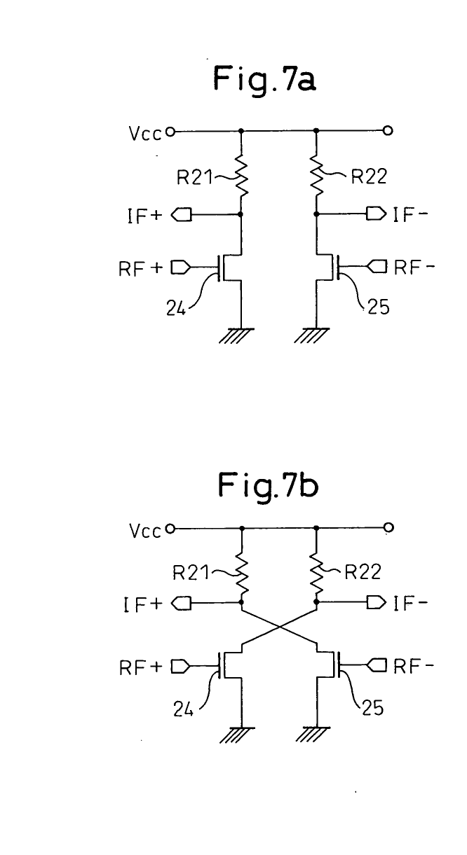

The operation of the Gilbert cell, i.e., the NMOS mixer of FIG. 6, will be described with reference to FIGS. 7a and 7b. For simplicity, it is assumed that the local signals are square waves. As the signals of the same sign are applied simultaneously to the FETs 26 and 29 and the FETs 27 and 28, respectively, if the FETs 26 and 29 are ON, the FETs 27 and 28 are OFF, and if the FETs 27 and 28 are ON, the FETs 26 and 29 are OFF. If the FETs 26 and 29 are ON, as shown in FIG. 7a, the resistor R21 is connected as the load for the FET 24. If the FETs 27 and 28 are ON, as shown in FIG. 7b, the resistor R22 is connected as the load for the FET 24. For the FET 25, the connection of the load is reversed from the case of the FET 24. In this way, the conditions of FIGS. 7a and 7b are alternately switched from one to the other in synchronism with the frequency of the square waveforms of the local signals.

This means that the condition switches alternately between the condition in which the input signal is output as is (by multiplying it by +1) and the condition in which the input signal is inverted for output (by multiplying it by −1) in synchronism with the input of each local signal. As a result, the intermediate-frequency (IF) signal of “5 GHz−4.9 GHz=100 MHz” is output as a differential output from the IF output terminal.

In the first embodiment, as the NMOS mixer is used as the mixer for obtaining the intermediate-frequency signal from the radio-frequency signal, a radio-frequency circuit permitting high packing density and having good frequency characteristics can be achieved.

(Polyphase Filter)

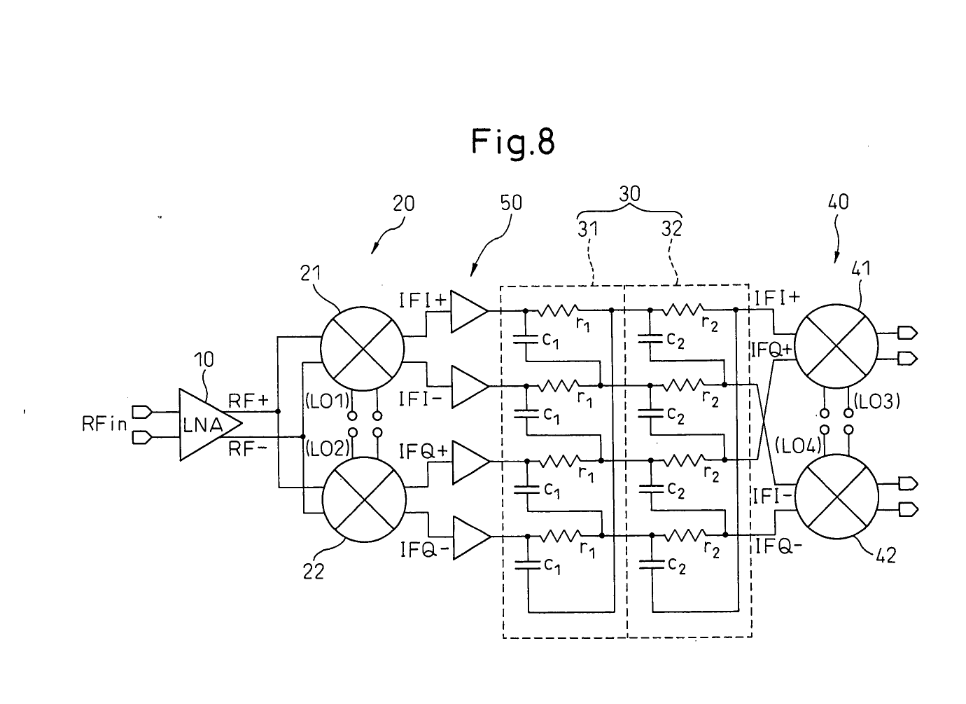

FIG. 8 is a diagram of the radio-frequency circuit of this embodiment, showing one specific example of the polyphase filter 30. In FIG. 2, the differential inputs and outputs were not explicitly shown, but in FIG. 8, the differential inputs and outputs are explicitly shown in order to explain the specific example of the polyphase filter 30.

As above described, the differential radio-frequency signals RF+ and RF− amplified by the low-noise amplifier 10 are both input to the multipliers 21 and 22 where they are multiplied by the local signals LO1 and LO2 displaced in phase by 90°, and intermediate-frequency signals IFI (IFI+ and IFI−) and IFQ (IFQ+ and IFQ−) displaced in phase by 90° are output. These intermediate-frequency signals are passed through buffers 50 (not shown in FIG. 2 but provided in the actual circuit) and fed to two stages of polyphase filters 31 and 32. In the polyphase filters 31 and 32, the intermediate-frequency signals IFI and IFQ of the predetermined frequency are shifted in phase, the former by +45° and the latter by −45°. The signals output from the polyphase filter are combined to obtain an intermediate-frequency signal with the image signal components canceled out.

In this embodiment, the polyphase filter is a two-stage filter comprising the polyphase filters 31 and 32. The polyphase filter 31 is formed by connecting four resistors r1 and four capacitances c1 as shown in the figure, and likewise, the polyphase filter 32 is formed by connecting four resistors r2 and four capacitances c2. In this embodiment, the capacitances c1 and c2 are chosen to have the same value, but the resistors r1 and r2 are chosen to have different values, to obtain the desired frequency band. In this embodiment, the polyphase filter of a two-stage configuration has been used, but if the filter is to be operated effectively over a wider band or a plurality of bands, the polyphase filter should be constructed from three or more stages.

(PMOS Mixer)

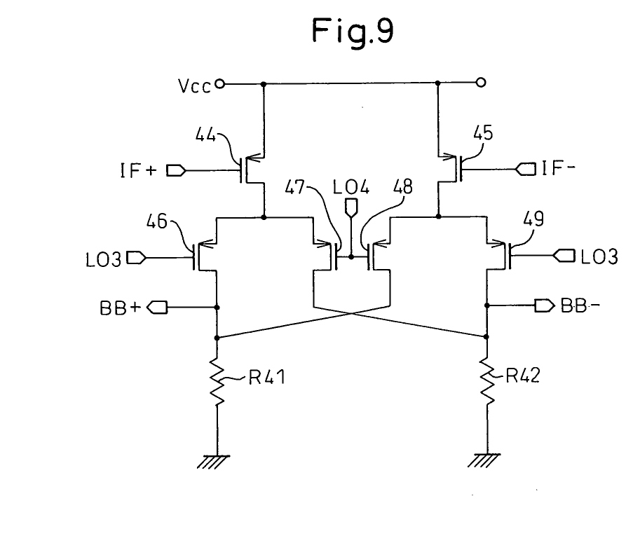

FIG. 9 shows a detailed circuit diagram of the PMOS mixer 40. The circuit configuration of the PMOS mixer 40 is similar to that of the NMOS mixer 20, except that the power supply line and the ground line are interchanged, as the carriers are holes. As shown in FIG. 9, the PMOS mixer 40 comprises PMOS FETs 44 to 49 and resistors R41 and R42. The intermediate-frequency signal with image signals removed from it by passing through the polyphase filter 30 is applied to the gates of the FETs 44 and 45. The differential pair FETs 46 and 47 are connected to the FET 44, while the differential pair FETs 48 and 49 are connected to the FET 45. The FETs 46 and 48 each forming one part of each differential pair are connected to the load resistor R41, and the FETs 47 and 49 each forming the other part of each differential pair are connected to the load resistor R42. The local signals LO3 and LO4 displaced in phase by 90° are applied to the FETs 46 and 49 and the FETs 47 and 48, respectively. With the FETs 46 and 49 repeatedly turned on and off in alternating fashion with the FETs 47 and 48, the FETs 44 and 45 are connected to the load R41 and the load R42 and vice versa in alternating fashion in synchronism with the inputs of the respective local signals. As a result, the baseband signal is output in the form of differential signals from the output terminals BB+ and BB−. The detailed operation is the same as that of the NMOS mixer 20, and therefore, a description thereof will not be repeated here.

Thus, as the PMOS mixer is used as the circuit for obtaining low-frequency signals such as the baseband signal, 1/f noise can be suppressed.

(Local Signal Generator)

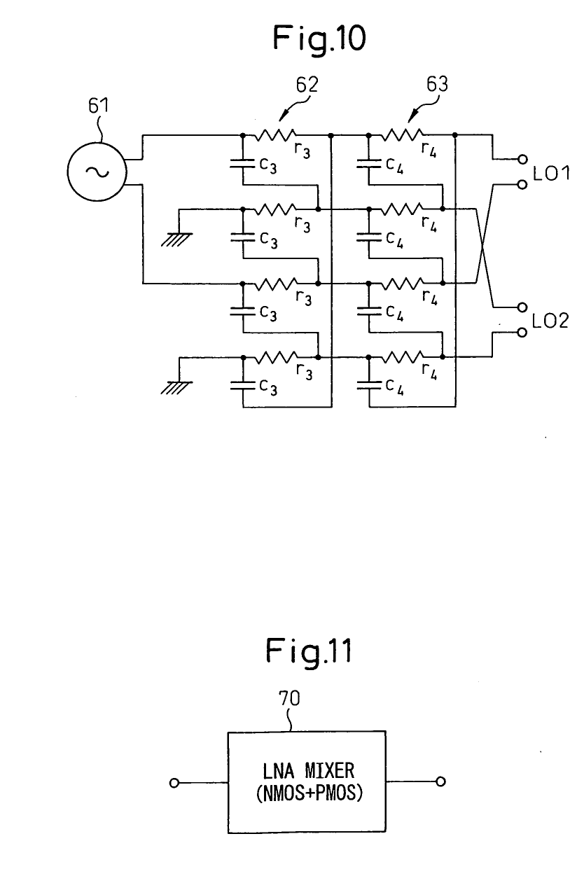

Next, referring to FIG. 10, a description will be given of the local oscillation circuit that generates the local signals to be supplied to the multipliers. FIG. 10 shows the local oscillation circuit that generates the local signals LO1 and LO2 to be used in the NMOS mixer 20. The oscillator signal from a local oscillator 61 is passed through two stages of polyphase filters 62 and 63 where a phase shift of +45° and a phase shift of −45° are introduced. The polyphase filters 62 and 63 are similar to the ones shown in FIG. 6, and are constructed by connecting C3 and r3 and C4 and r4 as shown in the figure. As a result, the local signals LO1 and LO2 displaced in phase by 90°, with unwanted image signals removed therefrom, are obtained. The number of stages of polyphase filters is also determined based on how wide the center frequency band for the 90° phase shift should be made.

FIG. 11 shows a block diagram of a second embodiment of the present invention. The second embodiment concerns a radio-frequency circuit 70 comprising an NMOS circuit as a low-noise amplifier and a PMOS circuit. In the second embodiment, the two-stage mixer configuration is not used, but a single mixer is used. The single mixer has a radio-frequency circuit formed from NMOS for processing the radio-frequency input signal and a switching circuit from PMOS. It should be noted that an additional low-noise amplifier may be provided at the front end of the radio-frequency circuit 70, and a gain-varying circuit may also be provided.

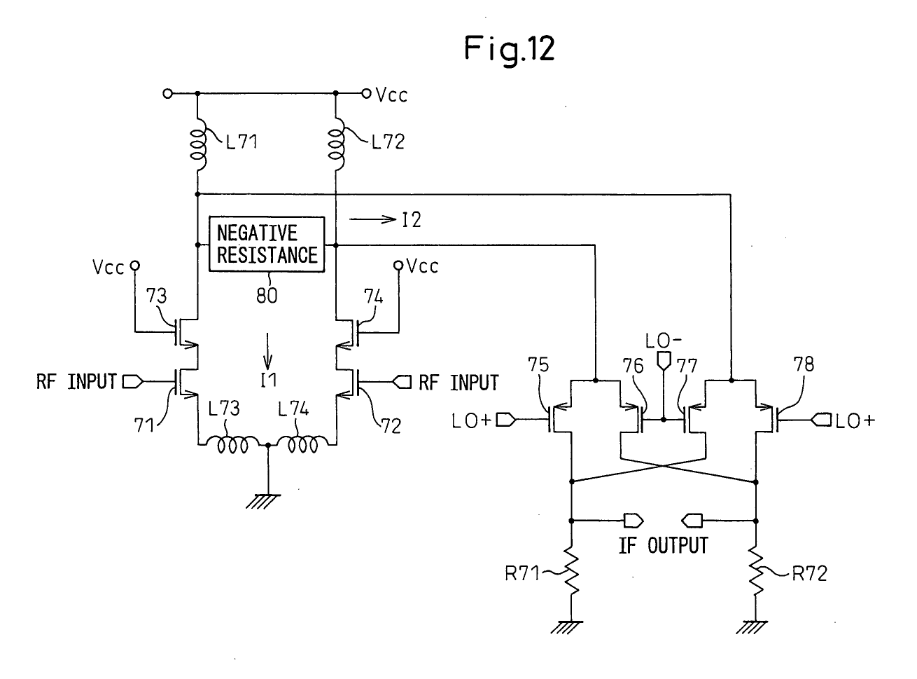

FIG. 12 is a detailed circuit diagram of the mixer according to the second embodiment. NMOS FETs 73 and 74 as cascode transistors are connected to voltage-to-current converting NMOS FETs 71 and 72, respectively, and are connected to the power supply via inductors L71 and L72, respectively. The reason that the inductors are used is that, since no voltage drop occurs across the inductors, the influence of a supply voltage drop, which can occur, for example, when a battery is used, can be reduced. In this embodiment, the FETs 71 and 72 are grounded via inductors L73 and L74, respectively. A negative resistance circuit 80 to be described in detail later is connected to the inductors L71 and L72.

The PMOS circuit as the switching circuit is connected to the inductors L71 and L72. The PMOS circuit comprises PMOSFETs 75 to 78 and resistors R71 and R72. The FETs 75 and 76 forming one differential pair and the FETs 77 and 78 forming the other differential pair are connected to the respectively corresponding load resistors R71 and R72. Each time the local (LO) signals displaced in phase by 90° are applied to the gates of the FETs 75 and 76 and the FETs 77 and 78, respectively, one FET in each differential pair is turned on, and the loads for the voltage-to-current converting NMOS FETs 71 and 72 are switched between the resistors R71 and R72. For example, as one NMOS FET 71, to which the RF signal is input, is connected to the differential pair PMOSFETs 77 and 78, the NMOS FET 71 is connected to the load resistor R72 if the FET 78 is ON, and to the load resistor R71 if the FET 77 is ON. This operation is similar to that described with reference to FIG. 4 in the first embodiment. In some cases, this PMOS circuit is called a mixer.

In the second embodiment, without using two stages of mixers connected via a polyphase filter but by using a single mixer having the circuit formed from NMOS acting as an LNA for processing the radio-frequency input signal and the switching circuit from PMOS, a radio-frequency circuit having good frequency characteristics and low 1/f noise at or near the DC can be achieved, as in the first embodiment. The second embodiment is effective for use as a direct-conversion receiver circuit that uses a local signal of the same frequency as the center frequency of the received signal.

The negative resistance circuit 80 is a circuit for compensating for performance degradation of the inductors L71 and L72. Usually, the load inductors L71 and L72 are each formed by winding wire in the form of a spiral coil on an IC chip, but the resistance is large and the Q cannot be made large. In this embodiment, the negative resistance circuit 80 is connected to the inductors L71 and L72 so that the negative resistance formed in the negative resistance circuit 80 is added to the resistance of the inductor L71 or L72 to cancel out the resistance of the coil.

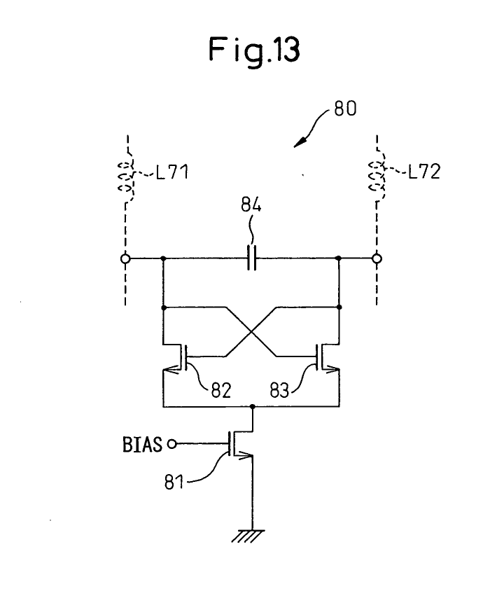

FIG. 13 shows one specific example of the negative resistance circuit 80. An NMOS FET 82 is connected to the coil L71, and an NMOS FET 83 is connected to the coil L72. The drain of the FET 82 is connected to the gate of the FET 83 whose drain is, in turn, connected to the gate of the FET 82. Further, a capacitor 84 is connected to the node between the coil L71 and the NMOS FET 82 and also to the node between the coil L72 and the NMOS FET 83. An NMOS FET 81 for applying a bias is connected to the sources of the FETs 82 and 83. The capacitor 84 is provided to determine the operating frequency band, but may be omitted depending on the circumstances.

For example, if the FET 71 (FIG. 12) is turned on because of an RF input, current flows through the coil L71 but, as the drain of the FET 82 is connected to the gate of the FET 83, the FET 83 is turned on, reducing the current flowing to the FET 82 and thus acting as a negative resistor. In terms of AC, the power line is regarded as ground; therefore, the situation is equivalent to connecting the negative resistor in parallel to the inductor L71, and the resistance of the inductor L71 is thus canceled out. Thus, a low-resistance and high-Q inductance can be used as the load.

When the present invention is applied, for example, to a wireless LAN, there arises a need to accommodate a plurality of frequencies (for example, 5 GHz and 2.4 GHz). However, when an inductor is used as the load, as in FIG. 12, the gain is large at the specific single frequency determined by the value of the inductance, but the gain drops at other frequencies. That is, large gain cannot be obtained at different frequencies or over a wide frequency band. In this embodiment, a plurality of LC resonant circuits are used in place of the inductor.

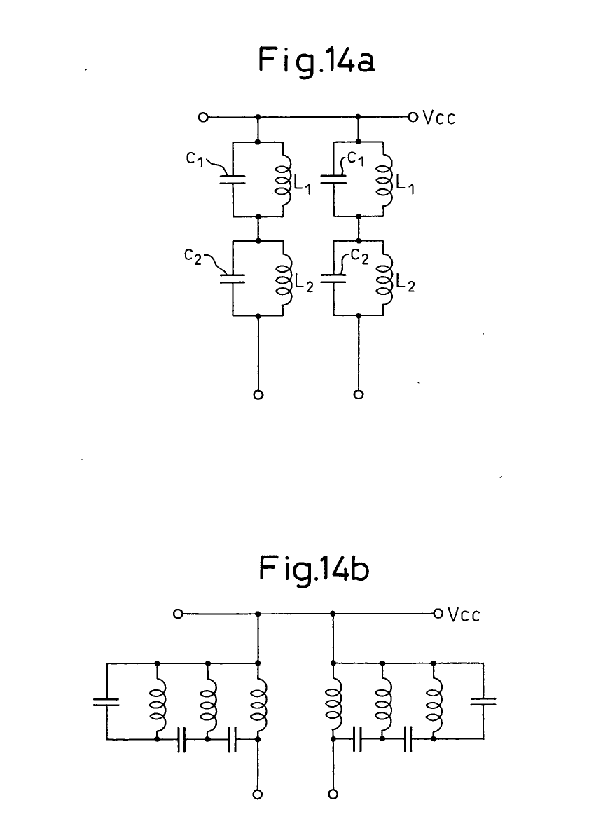

In FIG. 14a, an L1C1 resonant circuit and an L2C2 resonant circuit are used to replace each of the inductors L71 and L72 in FIG. 12. Large gain can be obtained at two frequencies f1(=½π\sqrt{L1C1}) and f2 (½π \sqrt{L2C2}) determined by L1C1 and L2C2. By increasing the number of resonant circuits, large gain can be obtained at as many frequencies as there are resonant circuits.

Further, to increase the frequency band, L's and C's should be connected in a ladder configuration as shown in FIG. 14b. In this case also, the number of L's and C's is determined according to the circuit design, and is not limited to the example shown here.

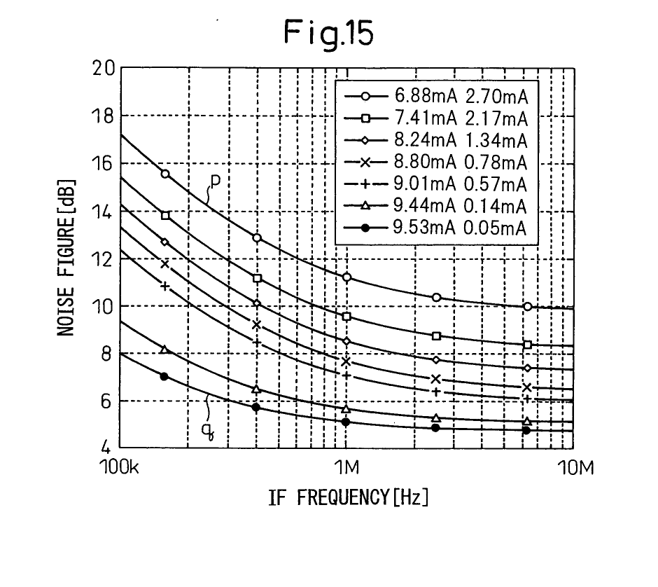

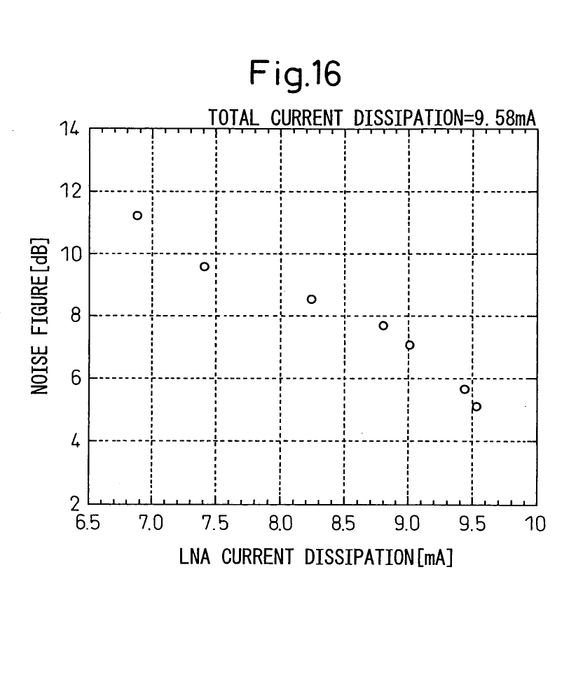

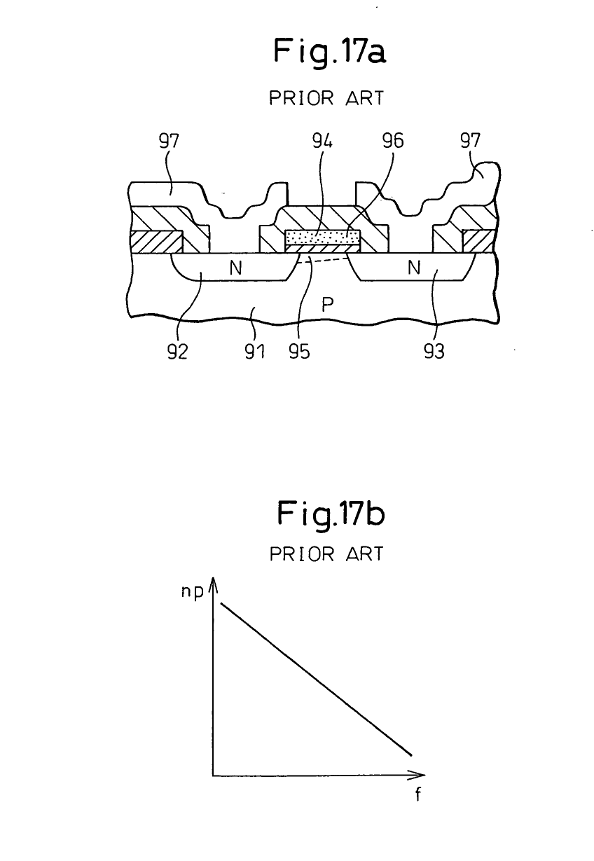

FIGS. 15 and 16 are graphs showing the results of a simulation which was conducted by, making the current I1 flowing to the NMOS circuit different from the current I2 flowing to the PMOS circuit in the second embodiment. The simulation was conducted using a circuit constructed by removing the negative resistance circuit 80 of FIG. 12 and connecting an additional PMOS circuit in parallel. That is, in this simulation circuit, the current I2 flows to the two PMOS circuits. The same parameters as those used at the design stage were used, and an ideal LO was used as the local signal. The total current consumption was fixed to 9.58 mA, and the gate bias voltages to the NMOS circuit and the PMOS circuits were varied, thereby varying the ratio of the current I1 in the NMOS circuit to the current I2 in the PMOS circuits.

FIG. 15 shows the IF frequency versus noise figure (NF) characteristics. The center frequency of the output IF frequency was 1 MHz, but data were taken over the range of 100 kHz to 10 MHz with 1 MHz as the center. As shown, the curve p represents the case where the current I1 in the NMOS circuit was 6.88 mA and the current I2 in the PMOS circuits was 2.70 mA (the ratio I1/I2 was 2.55); in this case, the noise figure at 1 MHz was 11.5 dB. As the ratio I1/I2 increases, the noise figure decreases monotonically. The curve q represents the case where the current I1 in the NMOS circuit was 9.53 mA and the current I2 in the PMOS circuits was 0.05 mA, the ratio being 190.6; in this case, at 1 MHz, the noise figure was reduced down to 5 dB. As noted above, in the simulation, the current I2 was the current flowing to the two PMOS circuits connected in parallel.

FIG. 16 is a diagram showing the results of FIG. 15 in a summarized form, the abscissa representing the current consumption of the NMOS circuit acting as the LNA and the ordinate representing the noise figure. As is apparent from the diagram, it can be seen that when the current flowing to the NMOS circuit is increased while holding the current flowing in the entire circuit at a constant value, the noise figure decreases monotonically. Accordingly, in the case of the second embodiment, it is preferable to drive the entire circuit so that a larger current flows in the NMOS circuit than in the PMOS circuit.

1. A radio-frequency circuit comprising:
an NMOS circuit acting as a low-noise amplifier; and
a PMOS circuit for switching a load for said NMOS circuit.

2. A radio-frequency circuit as claimed in claim 1, wherein said NMOS circuit is connected to a power supply via an inductor.

3. A radio-frequency circuit as claimed in claim 2, wherein said inductor is grounded via a negative resistance circuit.

4. A radio-frequency circuit as claimed in claim 1, wherein said NMOS circuit is connected to a power supply via a plurality of resonant circuits.

5. A radio-frequency circuit as claimed in claim 4, wherein said plurality of resonant circuits are grounded via a negative resistance circuit.

6. A radio-frequency circuit as claimed in claim 1, wherein said NMOS circuit is connected to a power supply via LC circuits connected in a ladder configuration.

7. A radio-frequency circuit as claimed in claim 1, wherein said LC circuits are grounded via a negative resistance circuit.

8. A radio-frequency circuit as claimed in claim 1, wherein said radio-frequency circuit is driven so that a larger current flows in said NMOS circuit than in said PMOS circuit.
